(19) United States
(12) Patent Application Publication
(10) Pub. No.: US 2024/0414975 A1
(43) Pub. Date: Dec. 12, 2024

(54) LIGHT-EMITTING ELEMENT AND DISPLAY DEVICE

(71) Applicant: Sharp Display Technology Corporation, Kameyama City, Mie (JP)

(72) Inventor: Shota NOMIYAMA, Kameyama City, Mie (JP)

(21) Appl. No.: 18/726,144

(22) PCT Filed: Mar. 23, 2022
(86) PCT No.: PCT/JP2022/013343

§ 371 Date: Jul. 2, 2024

(51) Int. Cl. H10K 59/80; H10K 59/35

(52) U.S. Cl. CPC H10K 59/80515; H10K 59/80517; H10K 59/80518; H10K 59/80521; H10K 59/80523; H10K 59/877; H10K 59/8792; H10K 59/35

(57) ABSTRACT

A light-emitting element includes: a first electrode including a first conductive layer and a second conductive layer, the first conductive layer being provided with a flat surface serving as an upper surface and reflecting visible light, and the second conductive layer being provided on the flat surface, transmitting the visible light, and including a first region having a first thickness, a second region positioned around the first region and having a second thickness thicker than the first thickness, and a third region positioned around the second region and having a third thickness thicker than the second thickness; a functional layer including at least a light-emitting layer and formed on the second conductive layer in conformity with a shape of the second conductive layer, and a second electrode formed on the functional layer and transmitting the visible light; and an edge cover containing at least one of a scattering material to scatter the visible light or a light-blocking material to block the visible light, covering at least a portion of an end portion of the first electrode, and formed higher than the second electrode.

### TECHNICAL FIELD

The present disclosure relates to a light-emitting element and a display device.

### BACKGROUND ART

In recent years, various display devices including light-emitting elements have been under development. In particular, display devices including organic light-emitting diodes (OLEDs) or quantum-dot light-emitting diodes (QLEDs) are significantly attracting attention because such display devices operate on lower power, have a thinner profile, and achieve higher image quality.

In the field of such display devices, interference effects of light between electrodes are utilized to improve color purity and light emission efficiency. Thus, a known fact is that, when a user views a display region of a display device from an oblique direction at a large viewing angle, a difference in optical path is produced compared with a case where the user views the display region of the display device from the front, and the optical path difference causes variations in color.

Patent Document 1 describes that an anode electrode is angled or shaped into a bowl to reduce viewing angle dependence of color variations seen with the display device.

### CITATION LIST

### Patent Literature

[Patent Document 1] International Publication No. WO/2019/188416A1

### SUMMARY

### Technical Problems

The display device described in Patent Document 1 has the anode electrode angled or shaped into a bowl. However, when the user views the display region of the display device from an oblique direction at a large viewing angle, a difference in optical path is also produced compared with a case where the user views the display region of the display device from the front, and the difference in optical path still causes variations in color of some light. As to the display device described in Patent Document 1, such light is directly lead to the eyes of the user. The problem is that the configuration of the display device cannot reduce the variations in color seen when the user views the display region of the display device from an oblique direction at a large viewing angle.

An aspect of the present disclosure is conceived in view of the above problem, and sets out to provide a light-emitting element and a display device that reduce viewing angle dependence of color variations, including color variations seen in viewing from an oblique direction at a large viewing angle.

### Solution to Problems

In order to solve the above problems, a light-emitting element according to the present disclosure includes:
a first electrode including a first conductive layer and a second conductive layer, the first conductive layer being provided with a flat surface serving as an upper surface and reflecting visible light, and the second conductive layer being provided on the flat surface, transmitting the visible light, and including a first region having a first thickness, a second region positioned around the first region and having a second thickness thicker than the first thickness, and a third region positioned around the second region and having a third thickness thicker than the second thickness;
a functional layer including at least a light-emitting layer and formed on the second conductive layer in conformity with a shape of the second conductive layer, and a second electrode formed on the functional layer and transmitting the visible light; and
an edge cover containing at least one of a scattering material to scatter the visible light or a light-blocking material to block the visible light, covering at least a portion of an end portion of the first electrode, and formed higher than the second electrode.

### Advantageous Effects of Disclosure

An aspect of the present disclosure can provide a light-emitting element and a display device that reduce viewing angle dependence of color variations, including color variations seen in viewing from an oblique direction at a large viewing angle.

### BRIEF DESCRIPTION OF DRAWINGS

FIG. 1 is a plan view illustrating a schematic configuration of a display device according to a first embodiment.

FIG. 2 is a cross-sectional view illustrating a schematic configuration of a substrate including a transistor included in the display device according to the first embodiment.

FIG. 3(a) is a cross-sectional view illustrating a schematic configuration of a red light-emitting element included in the display device according to the first embodiment. FIG. 3(b) is a cross-sectional view illustrating a schematic configuration of a green light-emitting element included in the display device according to the first embodiment. FIG. 3(c) is a cross-sectional view illustrating a schematic configuration of a blue light-emitting element included in the display device according to the first embodiment.

FIG. 4(a) is a view illustrating a schematic configuration of an edge cover included in each of the red light-emitting element, the green light-emitting element, and the blue light-emitting element of the display device according to the first embodiment. FIG. 4(b), FIG. 4(c), FIG. 4(d), and FIG. 4(e) are views illustrating schematic configurations of other edge covers that can be included in each of the red light-emitting element, the green light-emitting element, and the blue light-emitting element of the display device according to the first embodiment.

FIG. 5 is a cross-sectional view illustrating a schematic configuration of a display device according to a second embodiment.

FIG. 6 is a cross-sectional view illustrating a schematic configuration of a display device according to a third embodiment.

### DESCRIPTION OF EMBODIMENTS

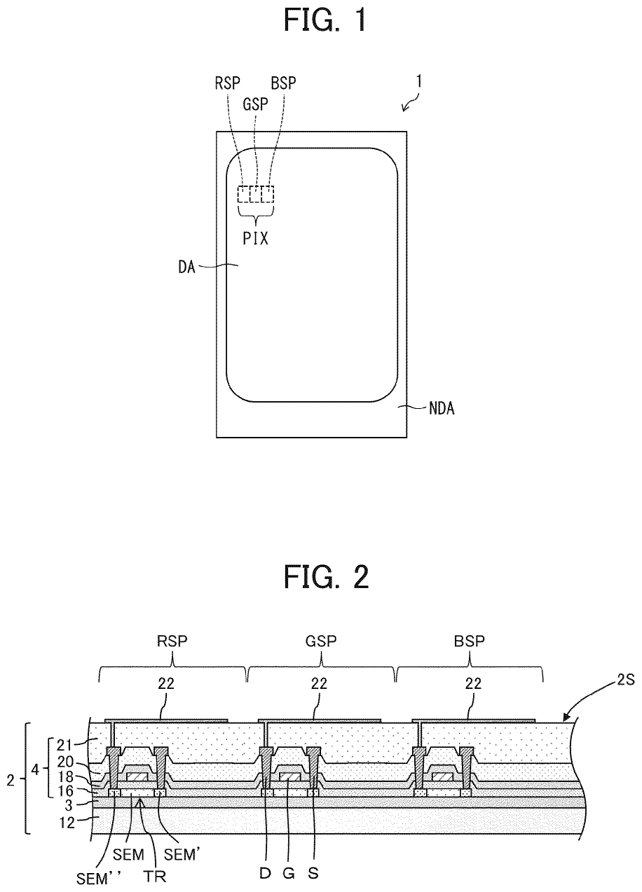

Described below are embodiments of the disclosure, with reference to FIGS. 1 to 6. For convenience in description, like reference signs designate identical constituent features throughout the embodiments. These constituent features will not be elaborated upon.

### First Embodiment

FIG. 1 is a plan view illustrating a schematic configuration of a display device 1 according to a first embodiment.

As illustrated in FIG. 1, the display device 1 includes a picture-frame region NDA and a display region DA. The display region DA of the display device 1 includes a plurality of pixels PIX. Each of the pixels PIX includes a red subpixel RSP, a green subpixel GSP, and a blue subpixel BSP. This embodiment exemplifies a case where one pixel PIX includes the red subpixel RSP, the green subpixel GSP, and the blue subpixel BSP. However, this embodiment shall not be limited to such a case. For example, the one pixel PIX may further include a subpixel in another color, in addition to the red subpixel RSP, the green subpixel GSP, and the blue subpixel BSP.

FIG. 2 is a cross-sectional view illustrating a schematic configuration of a substrate 2 including a transistor TR included in the display device 1 according to the first embodiment.

As illustrated in FIG. 2, the substrate 2 includes the transistor TR included in the display device 1. The substrate 2 includes, above a substrate 12, a barrier layer 3 and a thin-film transistor layer 4 provided on top of another from toward the substrate 12. The thin-film transistor layer 4 includes the transistor TR. Then, the substrate 2 including the transistor TR has a surface 2S provided with a first electrode 22.

The substrate 12 may be, for example, either a resin substrate made of a resin material such as polyimide, or a glass substrate. This embodiment exemplifies a case where the display device 1 is a flexible display device, and the substrate 12 is a resin substrate made of a resin material such as polyimide. However, this embodiment shall not be limited to such a case. If the display device 1 is a non-flexible display device, the substrate 12 may be a glass substrate.

The barrier layer 3 is a layer that prevents foreign substances such as water and oxygen from entering the transistor TR and the colored light-emitting elements to be described later. The barrier layer 3 may be a silicon oxide film, a silicon nitride film, or a silicon oxynitride film formed by chemical vapor deposition (CVD). Alternatively, the barrier layer 3 may be a multilayer film including these films.

The thin-film transistor layer 4 including the transistor TR has a transistor TR portion. The transistor TR portion includes: a semiconductor film SEM; doped semiconductor films SEM′ and SEM″; an inorganic insulating film 16; a gate electrode G; an inorganic insulating film 18; an inorganic insulating film 20; a source electrode S; a drain electrode D; and a planarization film 21. The thin-film transistor layer 4 including the transistor TR has another portion than the transistor TR portion. The other portion includes: the inorganic insulating film 16; the inorganic insulating film 18; the inorganic insulating film 20; and the planarization film 21.

The semiconductor films SEM, SEM′, and SEM″ may be formed of, for example, low-temperature polysilicon (LTPS) or an oxide semiconductor (e.g., an In—Ga—Zn—O-based semiconductor). This embodiment exemplifies a case where the transistor TR is a top-gate transistor. However, this embodiment shall not be limited to such a case. The transistor TR may be a bottom-gate transistor.

Each of the gate electrode G, the source electrode S, and the drain electrode D can be either a metal monolayer film, or a metal multilayer film, containing at least one of, for example, aluminum, tungsten, molybdenum, tantalum, chromium, titanium, or copper.

Each of the inorganic insulating film 16, the inorganic insulating film 18, and the inorganic insulating film 20 can be a silicon oxide film, a silicon nitride film, or a silicon oxynitride film formed by chemical vapor deposition (CVD). Alternatively, each of the inorganic insulating films 16, 18, and 20 can be a multilayer film including these films.

The planarization film 21 may be formed of, for example, an applicable organic material such as polyimide or acrylic.

As illustrated in FIG. 2, a plurality of the first electrodes 22 are controlled by the respective transistors TR, and the transistors TR are included in control circuits. The control circuits are provided to the thin-film transistor layer 4 including the transistors TR.

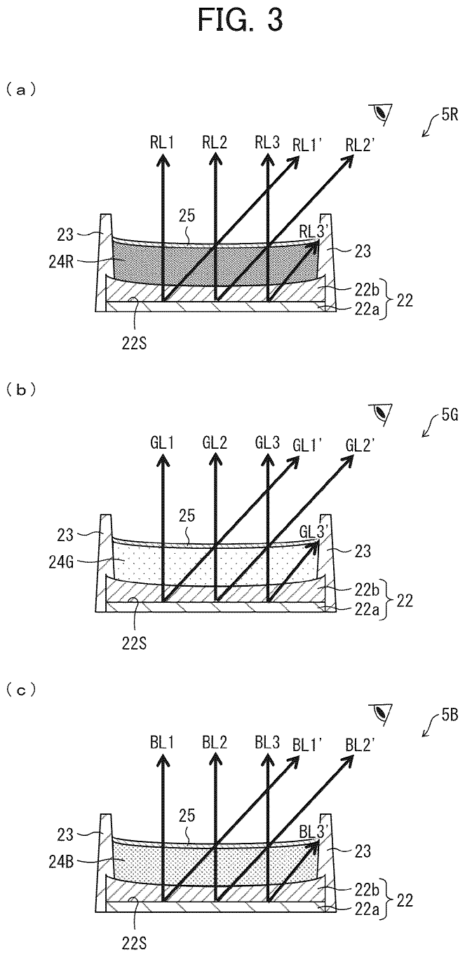

FIG. 3(a) is a cross-sectional view illustrating a schematic configuration of a red light-emitting element 5R included in the display device 1 according to the first embodiment. FIG. 3(b) is a cross-sectional view illustrating a schematic configuration of a green light-emitting element 5G included in the display device 1 according to the first embodiment. FIG. 3(c) is a cross-sectional view illustrating a schematic configuration of a blue light-emitting element 5B included in the display device 1 according to the first embodiment.

The red subpixel RSP illustrated in FIGS. 1 and 2 is provided with the red light-emitting element 5R. The green subpixel GSP illustrated in FIGS. 1 and 2 is provided with the green light-emitting element 5G. The blue subpixel BSP illustrated in FIGS. 1 and 2 is provided with the blue light-emitting element 5B.

As illustrated in FIG. 3(a), the red light-emitting element 5R includes: a first electrode 22; a functional layer 24R including a red light-emitting layer; and a second electrode 25, all of which are provided in the stated order from toward the substrate 2 including the transistor TR illustrated in FIG. 2.

As illustrated in FIG. 3(b), the green light-emitting element 5G includes: a first electrode 22; a functional layer 24G including a green light-emitting layer; and a second electrode 25, all of which are provided in the stated order from toward the substrate 2 including the transistor TR illustrated in FIG. 2.

As illustrated in FIG. 3(c), the blue light-emitting element 5B includes: a first electrode 22; a functional layer 24B including a blue light-emitting layer; and a second electrode 25, all of which are provided in the stated order from toward the substrate 2 including the transistor TR illustrated in FIG. 2.

This embodiment exemplifies a case where the red light-emitting element 5R, the green light-emitting element 5G, and the blue light-emitting element 5B have a forward-order stack structure including the first electrode 22 serving as an anode and the second electrode 25 serving as a cathode. However, this embodiment shall not be limited to such a case. The red light-emitting element 5R, the green light-emitting element 5G, and the blue light-emitting element 5B may have a reverse-order stack structure including the first electrode 22 serving as a cathode and the second electrode serving as an anode.

If the red light-emitting element 5R, the green light-emitting element 5G, and the blue light-emitting element 5B have the above forward-order stack structure, each of the functional layer 24R including the red light-emitting layer, the functional layer 24G including the green light-emitting layer, and the functional layer 24B including the blue light-emitting layer can include: a hole injection layer; a hole transport layer; the corresponding light-emitting layer; an electron transport layer; and an electron injection layer, all of which are provided in the stated order between the first electrode 22 and the second electrode 25 from toward the first electrode 22. Note that each of the functional layers may appropriately omit one or more layers except the corresponding light-emitting layer.

Furthermore, if the red light-emitting element 5R, the green light-emitting element 5G, and the blue light-emitting element 5B have the above reverse-order stack structure, each of the functional layer 24R including the red light-emitting layer, the functional layer 24G including the green light-emitting layer, and the functional layer 24B including the blue light-emitting layer can include: an electron injection layer; an electron transport layer; the corresponding light-emitting layer; a hole transport layer; and a hole injection layer, all of which are provided in the stated order between the first electrode 22 and the second electrode 25 from toward the first electrode 22. Note that each of the functional layers may appropriately omit one or more layers except the corresponding light-emitting layer.

If the red light-emitting element 5R, the green light-emitting element 5G, and the blue light-emitting element 5B illustrated in FIG. 3 have the above forward-order stack structure, the first electrode 22 serving as an anode is formed of an electrode material that reflects visible light, and the second electrode 25 serving as a cathode is formed of an electrode material that transmits visible light. Hence, the red light-emitting element 5R, the green light-emitting element 5G, and the blue light-emitting element 5B can be formed as top-emission light-emitting elements.

Furthermore, if the red light-emitting element 5R, the green light-emitting element 5G, and the blue light-emitting element 5B illustrated in FIG. 3 have the above reverse-order stack structure, the first electrode 22 serving as a cathode is formed of an electrode material that reflects visible light, and the second electrode 25 serving as an anode is formed of an electrode material that transmits visible light. Hence, the red light-emitting element 5R, the green light-emitting element 5G, and the blue light-emitting element 5B can be formed as top-emission light-emitting elements.

The red light-emitting element 5R illustrated in FIG. 3(a) includes: the first electrode 22 including a first conductive layer 22a and a second conductive layer 22b, the first conductive layer 22a being provided with a flat surface 22S serving as an upper surface and reflecting visible light, and the second conductive layer 22b being provided on the flat surface 22S, transmitting the visible light, and including a center region (a first region) having a first thickness, a peripheral region (a second region) positioned around the center region (the first region) and having a second thickness thicker than the first thickness, and an end portion region (a third region) positioned around the peripheral region (the second region) and having a third thickness thicker than the second thickness; the functional layer 24R including at least the red light-emitting layer and formed on the second conductive layer 22b in conformity with a shape of the second conductive layer 22b, and the second electrode 25 formed on the functional layer 24R and transmitting the visible light; and an edge cover 23 containing at least one of a scattering material to scatter the visible light or a light-blocking material to block the visible light, covering at least a portion of an end portion of the first electrode 22, and formed higher than the second electrode 25.

In this embodiment, the edge cover 23 can be formed of a photosensitive resin material containing a scattering material that scatters visible light. The photosensitive resin material is exposed to light and developed, and successfully patterned into a predetermined shape. Note that the photosensitive resin material contains a scattering material that scatters visible light, and is preferably made of a material photosensitive to a wavelength region shorter than the visible light.

The second conductive layer 22b is preferably formed to have a predetermined curvature, in order to become gradually thicker toward the edge cover 23. That is, the second conductive layer 22b has an upper surface preferably curved so that the upper surface becomes gradually thicker toward the edge cover 23. In this embodiment, the second conductive layer 22b included in the red light-emitting element 5R is formed to have a predetermined curvature, in order to become gradually thicker toward the edge cover 23. However, the second conductive layer 22b shall not be limited to such a configuration as long as the second conductive layer 22b includes the center region, the peripheral region, and the end portion region. Note that the center region of the second conductive layer 22b is provided farther from the edge cover 23 than the peripheral region of the second conductive layer 22b, and the end portion region of the second conductive layer 22b is provided closer to the edge cover 23 than the peripheral region of the second conductive layer 22b.

The green light-emitting element 5G illustrated in FIG. 3(b) includes: the first electrode 22 including a first conductive layer 22a and a second conductive layer 22b, the first conductive layer 22a being provided with a flat surface 22S serving as an upper surface and reflecting visible light, and the second conductive layer 22b being provided on the flat surface 22S, transmitting the visible light, and including a center region (a first region) having a first thickness, a peripheral region (a second region) positioned around the center region (the first region) and having a second thickness thicker than the first thickness, and an end portion region (a third region) positioned around the peripheral region (the second region) and having a third thickness thicker than the second thickness; the functional layer 24G including at least the green light-emitting layer and formed on the second conductive layer 22b in conformity with a shape of the second conductive layer 22b, and the second electrode 25 formed on the functional layer 24G and transmitting the visible light; and an edge cover 23 containing at least one of a scattering material to scatter the visible light or a light-blocking material to block the visible light, covering at least a portion of an end portion of the first electrode 22, and formed higher than the second electrode 25. The second conductive layer 22b is preferably formed to have a predetermined curvature, in order to become gradually thicker toward the edge cover 23. In this embodiment, the second conductive layer 22b included in the green light-emitting element 5G is formed to have a predetermined curvature, in order to become gradually thicker toward the edge cover 23. However, the second conductive layer 22b shall not be limited to such a configuration as long as the second conductive layer 22b includes the center region, the peripheral region, and the end portion region.

The blue light-emitting element 5B illustrated in FIG. 3(c) includes: the first electrode 22 including a first conductive layer 22a and a second conductive layer 22b, the first conductive layer 22a being provided with a flat surface 22S serving as an upper surface and reflecting visible light, and the second conductive layer 22b being provided on the flat surface 22S, transmitting the visible light, and including a center region (a first region) having a first thickness, a peripheral region (a second region) positioned around the center region (the first region) and having a second thickness thicker than the first thickness, and an end portion region (a third region) positioned around the peripheral region (the second region) and having a third thickness thicker than the second thickness; the functional layer 24B including at least the blue light-emitting layer and formed on the second conductive layer 22b in conformity with a shape of the second conductive layer 22b, and the second electrode 25 formed on the functional layer 24B and transmitting the visible light; and an edge cover 23 containing at least one of a scattering material to scatter the visible light or a light-blocking material to block the visible light, covering at least a portion of an end portion of the first electrode 22, and formed higher than the second electrode 25. The second conductive layer 22b is preferably formed to have a predetermined curvature, in order to become gradually thicker toward the edge cover 23. In this embodiment, the second conductive layer 22b included in the blue light-emitting element 5B is formed to have a predetermined curvature, in order to become gradually thicker toward the edge cover 23. However, the second conductive layer 22b shall not be limited to such a configuration as long as the second conductive layer 22b includes the center region, the peripheral region, and the end portion region.

The first conductive layer 22a includes, as the upper surface, the flat surface 22S that reflects visible light. The first conductive layer 22a may be any given visible-light-reflective and conductive layer formed of either a metal material such as, for example, Al, Mg, Li, and Ag, or an alloy of the metal materials. In this embodiment, the first conductive layer 22a is formed of, but is not limited to, Al.

The second conductive layer 22b provided on the flat surface 22S may be any given visible-light-transmitting and conductive layer. The second conductive layer 22b may be a thin film formed of, for example, either a transparent metal oxide (e.g., indium tin oxide, indium zinc oxide, and indium gallium zinc oxide), or a metal material such as Al, Mg, Li, and Ag. In this embodiment, the second conductive layer 22b is formed of, but is not limited to, a transparent metal oxide (i.e., indium tin oxide).

The second electrode 25 transmitting visible light may be any given visible-light-transmitting and conductive electrode. The second electrode 25 may be a thin film formed of, for example, either a transparent metal oxide (e.g., indium tin oxide, indium zinc oxide, and indium gallium zinc oxide), or a metal material such as Al, Mg, Li, and Ag. Alternatively, the second electrode 25 may be nano wires formed of a metal material such as Al and Ag. In this embodiment, the second electrode 25 is formed of, but is not limited to, a transparent metal oxide (i.e., indium tin oxide).

This embodiment exemplifies a case where, as illustrated in FIG. 3(a), FIG. 3(b), and FIG. 3(c), any of the red light-emitting element 5R, the green light-emitting element 5G, and the blue light-emitting element 5B included in the display device 1 includes: the first electrode 22 including the second conductive layer 22b having the center region, the peripheral region, and the end portion region; the functional layer including the corresponding light-emitting layer and formed on the second conductive layer 22b in conformity with the shape of the second conductive layer 22b, and the second electrode 25 transmitting the visible light; and the edge cover 23 containing at least one of a scattering material to scatter the visible light or a light-blocking material to block the visible light, at least partially covering a portion of an end portion of the first electrode 22, and formed higher than the second electrode 25. However, this embodiment shall not be limited to such a case. At least one of the red light-emitting element 5R, the green light-emitting element 5G, or the blue light-emitting element 5B included in the display device 1 may include: the first electrode 22 including the second conductive layer 22b having the center region, the peripheral region, and the end portion region; the functional layer including the corresponding light-emitting layer and formed on the second conductive layer 22b in conformity with the shape of the second conductive layer 22b, and the second electrode 25 transmitting the visible light; and the edge cover 23 containing at least one of a scattering material to scatter the visible light or a light-blocking material to block the visible light, at least partially covering a portion of an end portion of the first electrode 22, and formed higher than the second electrode 25.

As to the light-emitting element 5R illustrated in FIG. 3(a), between the flat surface 22S reflecting visible light and the second electrode 25, a portion including the end portion region of the second conductive layer 22b is the thickest, a portion including the center region of the second conductive layer 22b is the thinnest, and a portion including the peripheral region of the second conductive layer 22b is intermediate in thickness between the portion including the end portion region of the second conductive layer 22b and the portion including the center region of the second conductive layer 22b. Such a feature can reduce a difference in optical path from the flat surface 22S reflecting visible light until passing through the second electrode 25, between a reflected light ray RL1 reflected in the front direction passing through above the peripheral region of the second conductive layer 22b and a reflected light ray RL1′ reflected in an oblique direction passing through above the center region of the second conductive layer 22b. Furthermore, the difference in optical path from the flat surface 22S reflecting visible light until passing through the second electrode 25 is relatively small between a reflected light ray RL2 reflected in the front direction passing through above the center region of the second conductive layer 22b and a reflected light ray RL2′ reflected in an oblique direction passing through above the peripheral region of the second conductive layer 22b. Whereas, the difference in optical path from the flat surface 22S reflecting visible light until passing through the second electrode 25 is large between a reflected light ray RL3 reflected in the front direction passing through above the peripheral region of the second conductive layer 22b and a reflected light ray RL3′ reflected in an oblique direction passing through above an edge of the end portion region of the second conductive layer 22b. However, the reflected light ray RL3′ is scattered, blocked, or scattered and blocked by the edge cover 23 containing at least one of the scattering material to scatter the visible light or the light-blocking material to block the visible light. Thanks to such a feature, the red light-emitting element 5R can reduce viewing angle dependence of color variations, including color variations seen in viewing from an oblique direction at a large viewing angle.

As to the green light-emitting element 5G illustrated in FIG. 3(b), between the flat surface 22S reflecting visible light and the second electrode 25, a portion including the end portion region of the second conductive layer 22b is the thickest, a portion including the center region of the second conductive layer 22b is the thinnest, and a portion including the peripheral region of the second conductive layer 22b is intermediate in thickness between the portion including the end portion region of the second conductive layer 22b and the portion including the center region of the second conductive layer 22b. Such a feature can reduce a difference in optical path from the flat surface 22S reflecting visible light until passing through the second electrode 25, between a reflected light ray GL1 reflected in the front direction passing through above the peripheral region of the second conductive layer 22b and a reflected light ray GL1′ reflected in an oblique direction passing through above the center region of the second conductive layer 22b. Furthermore, the difference in optical path from the flat surface 22S reflecting visible light until passing through the second electrode 25 is relatively small between a reflected light ray GL2 reflected in the front direction passing through above the center region of the second conductive layer 22b and a reflected light ray GL2′ reflected in an oblique direction passing through above the peripheral region of the second conductive layer 22b. Whereas, the difference in optical path from the flat surface 22S reflecting visible light until passing through the second electrode 25 is large between a reflected light ray GL3 reflected in the front direction passing through above the peripheral region of the second conductive layer 22b and a reflected light ray GL3′ reflected in an oblique direction passing through above an edge of the end portion region of the second conductive layer 22b. However, the reflected light ray RL3′ is scattered, blocked, or scattered and blocked by the edge cover 23 containing at least one of the scattering material to scatter the visible light or the light-blocking material to block the visible light. Thanks to such a feature, the green light-emitting element 5G can reduce viewing angle dependence of color variations, including color variations seen in viewing from an oblique direction at a large viewing angle.

As to the light-emitting element 5B illustrated in FIG. 3(c), between the flat surface 22S reflecting visible light and the second electrode 25, a portion including the end portion region of the second conductive layer 22b is the thickest, a portion including the center region of the second conductive layer 22b is the thinnest, and a portion including the peripheral region of the second conductive layer 22b is intermediate in thickness between the portion including the end portion region of the second conductive layer 22b and the portion including the center region of the second conductive layer 22b. Such a feature can reduce a difference in optical path from the flat surface 22S reflecting visible light until passing through the second electrode 25, between a reflected light ray BL1 reflected in the front direction passing through above the peripheral region of the second conductive layer 22b and a reflected light ray BL1′ reflected in an oblique direction passing through above the center region of the second conductive layer 22b. Furthermore, the difference in optical path from the flat surface 22S reflecting visible light until passing through the second electrode 25 is relatively small between a reflected light ray BL2 reflected in the front direction passing through above the center region of the second conductive layer 22b and a reflected light ray BL2′ reflected in an oblique direction passing through above the peripheral region of the second conductive layer 22b. Whereas, the difference in optical path from the flat surface 22S reflecting visible light until passing through the second electrode 25 is large between a reflected light ray BL3 reflected in the front direction passing through above the peripheral region of the second conductive layer 22b and a reflected light ray BL3′ reflected in an oblique direction passing through above an edge of the end portion region of the second conductive layer 22b. However, the reflected light ray BL3′ is scattered, blocked, or scattered and blocked by the edge cover 23 containing at least one of the scattering material to scatter the visible light or the light-blocking material to block the visible light. Thanks to such a feature, the blue light-emitting element 5B can reduce viewing angle dependence of color variations, including color variations seen in viewing from an oblique direction at a large viewing angle.

Note that the second conductive layer 22b including the center region, the peripheral region, and the end portion region can be formed by a method below. First, the second conductive layer 22b is formed flat. Then, a photosensitive resist layer is formed on the entire surface of the second conductive layer 22b formed flat. After that, the photosensitive resist layer is exposed to light using a halftone mask, and developed using a predetermined developing solution. Hence, the photosensitive resist layer is formed to include: the center region having the thinnest thickness, the end portion region having the thickest thickness, and the peripheral region having the intermediate thickness. Then, the photosensitive resist layer having different thicknesses and a portion of the second conductive layer 22b formed flat are removed by dry etching or wet etching. Hence, the second conductive layer 22b is formed to include: the center region having the thinnest thickness, the end portion region having the thickest thickness, and the peripheral region having the intermediate film thickness. In this embodiment, the photosensitive resist layer is exposed to light and developed, and formed to become gradually thicker toward the edge cover 23. As a result, the second conductive layer 22b is formed to have a predetermined curvature, in order to become gradually thicker toward the edge cover 23.

This embodiment exemplifies a case where each of the red light-emitting layer included in the red light-emitting element 5R, the green light-emitting layer included in the green light-emitting element 5G, and the blue light-emitting layer included in the blue light-emitting element 5B is an organic light-emitting layer formed by vapor deposition. However, this embodiment shall not be limited to such a case. Each of the red light-emitting layer, the green light-emitting layer, and the blue light-emitting layer may be a light-emitting layer containing quantum dots as long as each light-emitting layer can be formed in conformity with the shape of the second conductive layer 22b.

Furthermore, preferably, the red light-emitting element 5R illustrated in FIG. 3(a) has the second conductive layer 22b formed to have a first curvature, the green light-emitting element 5G illustrated in FIG. 3(b) has the second conductive layer 22b formed to have a second curvature, and the blue light-emitting element 5B illustrated in FIG. 3(c) has the second conductive layer 22b formed to have a third curvature. The first curvature is preferably smaller than the second curvature and the third curvature. Moreover, the second curvature is preferably smaller than the third curvature.

Thanks to the above features, the first curvature is smaller than the second curvature and the third curvature. Hence, the features can reduce color variations of a red light that typically exhibits larger color variations than a green light and a blue light. Furthermore, the second curvature is smaller than the third curvature. Hence, the features can reduce color variations of a green light that typically exhibits larger color variations than a blue light.

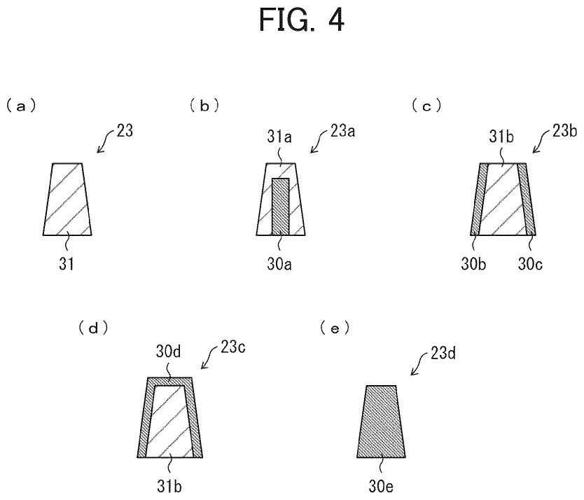

FIG. 4(a) is a view illustrating a schematic configuration of the edge cover 23 included in each of the red light-emitting element 5R, the green light-emitting element 5G, and the blue light-emitting element 5B of the display device 1 according to the first embodiment. FIG. 4(b), FIG. 4(c), FIG. 4(d), and FIG. 4(e) are views illustrating schematic configurations of other edge covers 23a, 23b, 23c, and 23d that can be included in each of the red light-emitting element 5R, the green light-emitting element 5G, and the blue light-emitting element 5B of the display device 1 according to the first embodiment.

The edge cover 23 illustrated in FIG. 4(a) is formed of a second edge cover 31 made of a photosensitive resin material containing a scattering material to scatter visible light. As the scattering material to scatter visible light, commercially available particles can be appropriately used to scatter the visible light. The edge cover 23 can scatter the reflected light reflected on the flat surface 22S that reflects visible light. Such a feature can provide the light-emitting elements with high light emission efficiency.

The edge cover 23a illustrated in FIG. 4(b) includes: a first edge cover 30a formed of a photosensitive resin material containing carbon black to absorb visible light and serving as a light-blocking material to block the visible light; and a second edge cover 31a formed of a photosensitive resin material containing a scattering material to scatter visible light. Furthermore, the first edge cover 30a is covered with the second edge cover 31a. This embodiment exemplifies a case where the light-blocking material to be used to block visible light is carbon black that absorbs visible light. However, this embodiment shall not be limited to such a case. For example, the material to be used can be either a metal material or commercially available particles, both of which reflect visible light. The edge cover 23a can block and scatter the reflected light reflected on the flat surface 22S that reflects visible light. Such a feature can provide the light-emitting elements with an excellent balance of light emission efficiency and an advantageous effect of reducing color variations.

The edge cover 23b illustrated in FIG. 4(c) includes: a second edge cover 31b; and first edge covers 30b and 30c each provided to a portion of a surface of the second edge cover 31b; that is, for example, an angled surface of the second edge cover 31b. The first edge covers 30b and 30c are formed of a photosensitive resin material containing carbon black that absorbs visible light and serves as a light-blocking material to block the visible light. Note that the second edge cover 31b may be formed either of a material to transmit visible light, or of a photosensitive resin material containing a scattering material to scatter visible light. The edge cover 23b can block reflected light reflected on the flat surface 22S that reflects visible light. Such a feature can provide the light-emitting elements with an advantageous effect of reducing color variations.

The edge cover 23c illustrated in FIG. 4(d) includes: the second edge cover 31b; and a first edge cover 30d provided to an entire surface of the second edge cover 31b, and formed of a photosensitive resin material containing carbon black that absorbs visible light and serves as a light-blocking material to block the visible light. The edge cover 23c can block reflected light reflected on the flat surface 22S that reflects visible light. Such a feature can provide the light-emitting elements with an advantageous effect of reducing color variations.

The edge cover 23d illustrated in FIG. 4(e) includes: a first edge cover 30e formed of a photosensitive resin material containing carbon black that absorbs visible light and serves as a light-blocking material to block the visible light. The edge cover 23d can block reflected light reflected on the flat surface 22S that reflects visible light. Such a feature can provide the light-emitting elements with an advantageous effect of reducing color variations.

### Second Embodiment

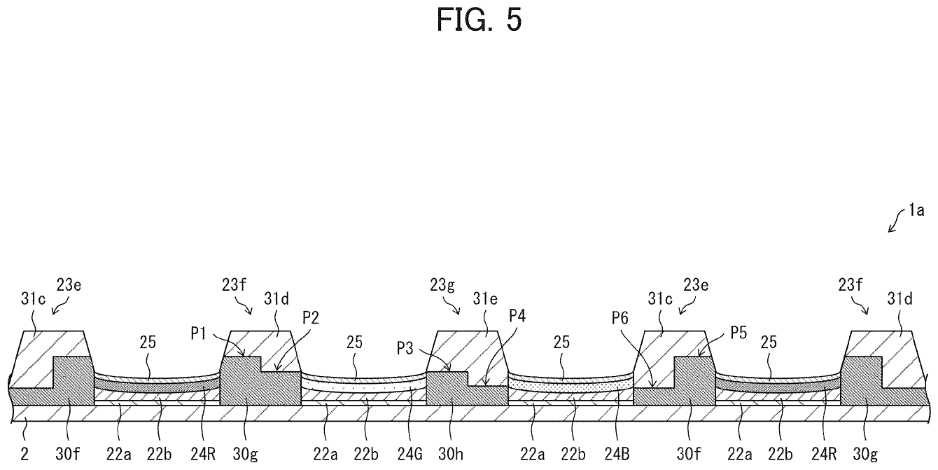

Described next is a second embodiment of the disclosure, with reference to FIG. 5. A display device 1a of this embodiment is different from the display device 1 of the first embodiment as follows. Second edge covers 31c, 31d, and 31e containing a scattering material to scatter visible light are provided on first edge covers 30f, 30g, and 30h containing a light-blocking material to block visible light, and, near a blue light-emitting layer included in the blue light-emitting element 5B and typically exhibiting low light emission efficiency, a fourth portion P4 and a sixth portion P6 are arranged. The fourth portion P4 is lower in height than a third portion P3 of the first edge cover 30h containing a light-blocking material to block visible light, and the sixth portion P6 is lower in height than a fifth portion P5 of the first edge cover 30f containing a light-blocking material to block visible light. Otherwise, the display device 1a is the same as the display device 1 of the first embodiment. For convenience in description, like reference signs designate identical constituent features throughout the drawings between this embodiment and the first embodiment. These constituent features will not be elaborated upon.

FIG. 5 is a cross-sectional view illustrating a schematic configuration of the display device 1a according to the second embodiment.

As illustrated in FIG. 5, the red light-emitting element 5R and the green light-emitting element 5G partially share an edge cover 23f, the green light-emitting element 5G and the blue light-emitting element 5B partially share an edge cover 23g, and the blue light-emitting element 5B and the red light-emitting element 5R partially share an edge cover 23e.

In the display device 1a, the second edge covers 31c, 31d, and 31e containing a scattering material to scatter visible light are provided on the first edge covers 30f, 30g, and 30h containing a light-blocking material to block visible light. Furthermore, this embodiment exemplifies a case where, in the display device 1a, the edge covers 23e, 23f, and 23g are equal in height. However, this embodiment shall not be limited to such a case. The edge covers 23e, 23f, and 23g may be different in height.

As illustrated in FIG. 5, the display device 1a has features as follows. The edge cover (a first shared edge cover) 23f includes a first portion P1 and a second portion P2 provided to the first edge cover 30g, and the first portion P1 of the first edge cover 30g is higher in height and the second portion P2 of the first edge cover 30g is lower in height. The edge cover (a second shared edge cover) 23g includes a third portion P3 and a fourth portion P4 provided to the first edge cover 30h, and the third portion P3 of the first edge cover 30h is higher in height and the fourth portion P4 of the first edge cover 30h is lower in height. The edge cover (a third shared edge cover) 23e includes a fifth portion P5 and a sixth portion P6 provided to the first edge cover 30f, and the fifth portion P5 of the first edge cover 30f is higher in height and the sixth portion P6 of the first edge cover 30f is lower in height.

Furthermore, as illustrated in FIG. 5, the display device 1a shows an example in which the first portion P1 provided to the first edge cover 30g containing a light-blocking material to block visible light is as high in height as the fifth portion P5 provided to the first edge cover 30f containing a light-blocking material to block visible light, the second portion P2 provided to the first edge cover 30g containing a light-blocking material to block visible light is as high in height as the third portion P3 provided to the first edge cover 30h containing a light-blocking material to block visible light, and the fourth portion P4 provided to the first edge cover 30h containing a light-blocking material to block visible light is as high in height as the sixth portion P6 provided to the first edge cover 30f containing a light-blocking material to block visible light. However, the display device 1a shall not be limited to such an example.

The display device 1a of this embodiment has features as follows. A relationship of (the height of the first portion P1 provided to the first edge cover 30g=the height of the fifth portion P5 provided to the first edge cover 30f)>(the height of the second portion P2 provided to the first edge cover 30g=the height of the third portion P3 provided to the first edge cover 30h)>(the height of the fourth portion P4 provided to the first edge cover 30h=the height of the sixth portion P6 provided to the first edge cover 30f) holds. The first portion P1 and the fifth portion P5 are provided near the red light-emitting layer included in the red light-emitting element 5R. The second portion P2 and the third portion P3 are provided near the green light-emitting layer included in the green light-emitting element 5G. The fourth portion P4 and the sixth portion P6 are provided near the blue light-emitting layer included in the blue light-emitting element 5B.

The display device 1a has: a first edge cover higher in height and formed near the red light-emitting layer included in the red light-emitting element 5R and typically exhibiting large color variations; a first edge cover lower in height and formed near the blue light-emitting layer included in the blue light-emitting element 5B and typically exhibiting low light emission efficiency; and a first edge cover having an intermediate height and formed near the green light-emitting layer included in the green light-emitting element 5G and exhibiting color variations smaller than color variations of the red light-emitting layer included in the red light-emitting element 5R. Such features can provide the display device 1a with an excellent balance of light emission efficiency and an advantageous effect of reducing color variations.

Note that the first edge covers 30f, 30g, and 30h can be formed of a photosensitive resin material containing a light-blocking material to block visible light. The photosensitive resin material is exposed to light with a half-tone mask and developed to form the first edge covers 30f, 30g, and 30h.

### Third Embodiment

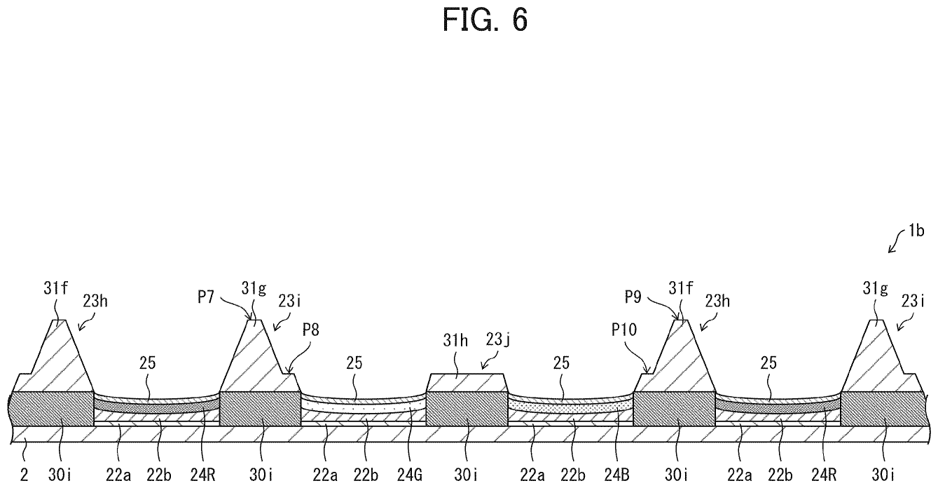

Described next is a third embodiment of the disclosure, with reference to FIG. 6. A display device 1b of this embodiment is different from the display device 1 of the first embodiment and the display device 1a of the second embodiment as follows. Second edge covers 31f, 31g, and 31h containing a scattering material to scatter visible light are provided on first edge covers 30i containing a light-blocking material to block visible light, and, near the blue light-emitting layer included in the blue light-emitting element 5B and typically exhibiting low light emission efficiency, a second edge cover 31h and a tenth portion P10 are arranged. The second edge cover 31h contains a scattering material to scatter visible light, and the tenth portion P10 is lower in height than a ninth portion P9 of the second edge cover 31f containing a scattering material to scatter visible light. Otherwise, the display device 1b of this embodiment is the same as the display devices 1 and 1a of the first and second embodiments. For convenience in description, like reference signs designate identical constituent features throughout the drawings between this embodiment and the first and second embodiments. These constituent features will not be elaborated upon.

FIG. 6 is a cross-sectional view illustrating a schematic configuration of the display device 1b according to the third embodiment.

As illustrated in FIG. 6, the red light-emitting element 5R and the green light-emitting element 5G partially share an edge cover 23i, the green light-emitting element 5G and the blue light-emitting element 5B partially share an edge cover 23j, and the blue light-emitting element 5B and the red light-emitting element 5R partially share an edge cover 23h.

In the display device 1b, the second edge covers 31f, 31g, and 31h containing a scattering material to scatter visible light are provided on the first edge covers 30i containing a light-blocking material to block visible light. Furthermore, this embodiment exemplifies a case where, in the display device 1b, the first edge covers 30i containing a light-blocking material to block visible light are equal in height. However, this embodiment shall not be limited to such a case.

As illustrated in FIG. 6, the display device 1b has features as follows. The first edge cover 30i of the edge cover (a first shared edge cover) 23i, the first edge cover 30i of the edge cover (a second shared edge cover) 23j, and the first edge cover 30i of the edge cover (a third shared edge cover) 23h are equal in height. The edge cover (the first shared edge cover) 23i includes a seventh portion P7 and an eighth portion P8 provided to the second edge cover 31g containing a scattering material to scatter visible light, and the seventh portion P7 of the second edge cover 31g is higher in height and the eighth portion P8 of the second edge cover 31g is lower in height. In the edge cover (the second shared edge cover) 23j, the second edge cover 31h containing a scattering material to scatter visible light is constant in height. The edge cover (the third shared edge cover) 23h includes the ninth portion P9 and the tenth portion P10 provided to the second edge cover 31f containing a scattering material to scatter visible light, and the ninth portion P9 of the second edge cover 31f is higher in height and the tenth portion P10 of the second edge cover 31f is lower in height.

Furthermore, as illustrated in FIG. 6, the display device 1b shows an example in which the seventh portion P7 provided to the second edge cover 31g containing a scattering material to scatter visible light is as high in height as the ninth portion P9 provided to the second edge cover 31f containing a scattering material to scatter visible light, and the eighth portion P8 provided to the second edge cover 31g containing a scattering material to scatter visible light, the tenth portion P10 provided to the second edge cover 31f containing a scattering material to scatter visible light, and the second edge cover 31h included in the edge cover (the second shared edge cover) 23j and containing a scattering material to scatter visible light are equal in height. However, the display device 1b shall not be limited to such an example.

The display device 1b of this embodiment has features as follows. A relationship of (the height of the seventh portion P7 provided to the second edge cover 31g=the height of the ninth portion P9 provided to the second edge cover 31f)> (the height of the eighth portion P8 provided to the second edge cover 31g=the height of the tenth portion P10 provided to the second edge cover 31f)=(the height of the second edge cover 31h) holds. The seventh portion P7 and the ninth portion P9 are provided near the red light-emitting layer included in the red light-emitting element 5R. The eighth portion P8 and the second edge cover 31h are provided near the green light-emitting layer included in the green light-emitting element 5G. The tenth portion P10 and the second edge cover 31h are provided near the blue light-emitting layer included in the blue light-emitting element 5B.

The display device 1b has: a second edge cover higher in height and formed near the red light-emitting layer included in the red light-emitting element 5R and typically exhibiting large color variations; a second edge cover lower in height and formed near the blue light-emitting layer included in the blue light-emitting element 5B and typically exhibiting low light emission efficiency; and a second edge cover lower in height and formed near the green light-emitting layer included in the green light-emitting element 5G and exhibiting color variations smaller than color variations of the red light-emitting layer included in the red light-emitting element 5R. Such features can provide the display device 1b with an excellent balance of light emission efficiency and an advantageous effect of reducing color variations.

Note that the second edge covers 31f, 31g, and 31h can be formed of a photosensitive resin material containing a scattering material to scatter visible light. The photosensitive resin material is exposed to light with a half-tone mask and developed to form the second edge covers 31f, 31g, and 31h.

### SUMMARY

### First Aspect

A light-emitting element, comprising: a first electrode including a first conductive layer and a second conductive layer, the first conductive layer being provided with a flat surface serving as an upper surface and reflecting visible light, and the second conductive layer being provided on the flat surface, transmitting the visible light, and including a first region having a first thickness, a second region positioned around the first region and having a second thickness thicker than the first thickness, and a third region positioned around the second region and having a third thickness thicker than the second thickness;
a functional layer including at least a light-emitting layer and formed on the second conductive layer in conformity with a shape of the second conductive layer, and a second electrode formed on the functional layer and transmitting the visible light; and
an edge cover containing at least one of a scattering material to scatter the visible light or a light-blocking material to block the visible light, covering at least a portion of an end portion of the first electrode, and formed higher than the second electrode.

### Second Aspect

The light-emitting element according to the first aspect, wherein the second conductive layer is formed to have a predetermined curvature.

### Third Aspect

The light-emitting element according to the first or second aspect, wherein the edge cover includes: a first edge cover containing the light-blocking material; and a second edge cover containing the scattering material.

### Fourth Aspect

The light-emitting element according to the third aspect, wherein the second edge cover is provided on the first edge cover.

### Fifth Aspect

The light-emitting element according to the third aspect, wherein the first edge cover is covered with the second edge cover.

### Sixth Aspect

The light-emitting element according to the first or second aspect, wherein the edge cover includes:
a second edge cover; and
a first edge cover containing the light-blocking material, and provided to at least a portion of a surface of the second edge cover.

### Seventh Aspect

The light-emitting element according to the first or second aspect, wherein the edge cover contains the scattering material.

### Eighth Aspect

The light-emitting element according to the first or second aspect, wherein the edge cover contains the light-blocking material.

### Ninth Aspect

The light-emitting element according to any one of the first to eighth aspects, wherein the first electrode is an anode, and
the second electrode is a cathode.

### Tenth Aspect

The light-emitting element according to any one of the first to eighth aspects, wherein the first electrode is a cathode, and
the second electrode is a anode.

### Eleventh Aspect

The light-emitting element according to any one of the first to tenth aspects, wherein the light-emitting layer contains either an organic light-emitting layer or quantum dots.

### Twelfth Aspect

A display device, comprising a plurality of the light-emitting elements according to any one of the first to eleventh aspects,
wherein the plurality of light-emitting elements include a first light-emitting element, a second light-emitting element, and a third light-emitting element,
the first light-emitting element emits light a center wavelength of which is closer to a long wavelength than a center wavelength of the second light-emitting element and a center wavelength of the third light-emitting element,
the second light-emitting element emits light the center wavelength of which is closer to a long wavelength than the center wavelength of the third light-emitting element.

### Thirteenth Aspect

The display device according to the twelfth aspect, wherein the first light-emitting element has the second conductive layer formed to have a first curvature,
the second light-emitting element has the second conductive layer formed to have a second curvature,
the third light-emitting element has the second conductive layer formed to have a third curvature, and
the first curvature is smaller than the second curvature and the third curvature.

### Fourteenth Aspect

The display device according to the thirteenth aspect, wherein the second curvature is smaller than the third curvature.

### Fifteenth Aspect

The display device according to any one of the twelfth to fourteenth aspects, wherein the first light-emitting element and the second light-emitting element partially share the edge cover,
the second light-emitting element and the third light-emitting element partially share the edge cover, and
the first light-emitting element and the third light-emitting element partially share the edge cover.

### Sixteenth Aspect

A display device, comprising a plurality of the light-emitting elements according to the fourth aspect,
wherein the plurality of light-emitting elements include a first light-emitting element, a second light-emitting element, and a third light-emitting element,
the first light-emitting element emits light a center wavelength of which is closer to a long wavelength than a center wavelength of the second light-emitting element and a center wavelength of the third light-emitting element,
the second light-emitting element emits light the center wavelength of which is closer to a long wavelength than the center wavelength of the third light-emitting element,
the edge cover shared between the first light-emitting element and the second light-emitting element is a first shared edge cover,
the edge cover shared between the second light-emitting element and the third light-emitting element is a second shared edge cover,
the edge cover shared between the first light-emitting element and the third light-emitting element is a third shared edge cover,
the first shared edge cover includes a first portion and a second portion provided to the first edge cover, the first portion of the first edge cover being higher in height and the second portion of the first edge cover being lower in height,
the second shared edge cover includes a third portion and a fourth portion provided to the first edge cover, the third portion of the first edge cover being higher in height and the fourth portion of the first edge cover being lower in height,
the third shared edge cover includes a fifth portion and a sixth portion provided to the first edge cover, the fifth portion of the first edge cover being higher in height and the sixth portion of the first edge cover being lower in height,
the first portion and the fifth portion are provided near a first light-emitting layer that is the light-emitting layer included in the first light-emitting element,
the second portion and the third portion are provided near a second light-emitting layer that is the light-emitting layer included in the second light-emitting element, and
the fourth portion and the sixth portion are provided near a third light-emitting layer that is the light-emitting layer included in the third light-emitting element.

### Seventeenth Aspect

The display device according to the sixteenth aspect, wherein the first portion is as high in height as the fifth portion,
the second portion is as high in height as the third portion, and
the fourth portion is as high in height as the sixth portion.

### Eighteenth Aspect

The display device according to the sixteenth or seventeenth aspect, wherein the first shared edge cover, the second shared edge cover, and the third shared edge cover are equal in height.

### Nineteenth Aspect

A display device, comprising a plurality of the light-emitting elements according to the fourth aspect,
wherein the plurality of light-emitting elements include a first light-emitting element, a second light-emitting element, and a third light-emitting element,
the first light-emitting element emits light a center wavelength of which is closer to a long wavelength than a center wavelength of the second light-emitting element and a center wavelength of the third light-emitting element,
the second light-emitting element emits light the center wavelength of which is closer to a long wavelength than the center wavelength of the third light-emitting element,
the edge cover shared between the first light-emitting element and the second light-emitting element is a first shared edge cover,
the edge cover shared between the second light-emitting element and the third light-emitting element is a second shared edge cover,
the edge cover shared between the first light-emitting element and the third light-emitting element is a third shared edge cover,
the first edge cover of the first shared edge cover, the first edge cover of the second shared edge cover, and the first edge cover of the third shared edge cover are equal in height,
the first shared edge cover includes a seventh portion and an eighth portion provided to the second edge cover, the seventh portion of the second edge cover being higher in height and the eighth portion of the second edge cover being lower in height,
in the second shared edge cover, the second edge cover is constant in height,
the third shared edge cover includes a ninth portion and a tenth portion provided to the second edge cover, the ninth portion of the second edge cover being higher in height and the tenth portion of the second edge cover being lower in height,
the seventh portion and the ninth portion are provided near a first light-emitting layer that is the light-emitting layer included in the first light-emitting element,
the eighth portion and the second edge cover of the second shared edge cover are provided near a second light-emitting layer that is the light-emitting layer included in the second light-emitting element, and
the tenth portion and the second edge cover of the second shared edge cover are provided near a third light-emitting layer that is the light-emitting layer included in the third light-emitting element.

### Twentieth Aspect

The display device according to the nineteenth aspect, wherein the seventh portion is as high in height as the ninth portion, and
the eighth portion, the tenth portion, and the second edge cover of the second shared edge cover are equal in height.

### Twenty First Aspect

The display device according to any one of the twelfth to twentieth aspects, wherein the first light-emitting element is a light-emitting element configured to emit a red light,
the second light-emitting element is a light-emitting element configured to emit a green light, and
the third light-emitting element is a light-emitting element configured to emit a blue light.

### Additional Remarks

The disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the disclosure. Moreover, the technical aspects disclosed in each embodiment may be combined together to achieve a new technical feature.

### INDUSTRIAL APPLICABILITY

The present disclosure is applicable to a light-emitting element and a display device.

1. A light-emitting element, comprising:
a first electrode including a first conductive layer and a second conductive layer, the first conductive layer being provided with a flat surface serving as an upper surface and reflecting visible light, and the second conductive layer being provided on the flat surface, transmitting the visible light, and including a first region having a first thickness, a second region positioned around the first region and having a second thickness thicker than the first thickness, and a third region positioned around the second region and having a third thickness thicker than the second thickness;
a functional layer including at least a light-emitting layer and formed on the second conductive layer in conformity with a shape of the second conductive layer, and a second electrode formed on the functional layer and transmitting the visible light; and
an edge cover containing at least one of a scattering material to scatter the visible light or a light-blocking material to block the visible light, covering at least a portion of an end portion of the first electrode, and formed higher than the second electrode.

2. The light-emitting element according to claim 1,
wherein the second conductive layer is formed to have a predetermined curvature.

3. The light-emitting element according to claim 1,
wherein the edge cover includes: a first edge cover containing the light-blocking material; and
a second edge cover containing the scattering material.

4. The light-emitting element according to claim 3,
wherein the second edge cover is provided on the first edge cover.

5. The light-emitting element according to claim 3,
wherein the first edge cover is covered with the second edge cover.

6. The light-emitting element according to claim 1,
wherein the edge cover includes:
a second edge cover; and
a first edge cover containing the light-blocking material, and provided to at least a portion of a surface of the second edge cover.

7. The light-emitting element according to claim 1,
wherein the edge cover contains the scattering material.

8. The light-emitting element according to claim 1,
wherein the edge cover contains the light-blocking material.

9. The light-emitting element according to claim 1,
wherein the first electrode is an anode, and
the second electrode is a cathode.

10. The light-emitting element according to claim 1,
wherein the first electrode is a cathode, and
the second electrode is an anode.

11. (canceled)

12. A display device, comprising
a plurality of the light-emitting elements according to claim 1,
wherein the plurality of light-emitting elements include a first light-emitting element, a second light-emitting element, and a third light-emitting element,
the first light-emitting element emits light a center wavelength of which is closer to a long wavelength than a center wavelength of the second light-emitting element and a center wavelength of the third light-emitting element, and
the second light-emitting element emits light the center wavelength of which is closer to a long wavelength than the center wavelength of the third light-emitting element.

13. The display device according to claim 12,
wherein the first light-emitting element has the second conductive layer formed to have a first curvature,
the second light-emitting element has the second conductive layer formed to have a second curvature,
the third light-emitting element has the second conductive layer formed to have a third curvature, and
the first curvature is smaller than the second curvature and the third curvature.

14. The display device according to claim 13,
wherein the second curvature is smaller than the third curvature.

15. The display device according to claim 12,
wherein the first light-emitting element and the second light-emitting element partially share the edge cover,
the second light-emitting element and the third light-emitting element partially share the edge cover, and
the first light-emitting element and the third light-emitting element partially share the edge cover.

16. A display device, comprising
a plurality of the light-emitting elements according to claim 4,
wherein the plurality of light-emitting elements include a first light-emitting element, a second light-emitting element, and a third light-emitting element,
the first light-emitting element emits light a center wavelength of which is closer to a long wavelength than a center wavelength of the second light-emitting element and a center wavelength of the third light-emitting element,
the second light-emitting element emits light the center wavelength of which is closer to a long wavelength than the center wavelength of the third light-emitting element,
the edge cover shared between the first light-emitting element and the second light-emitting element is a first shared edge cover,
the edge cover shared between the second light-emitting element and the third light-emitting element is a second shared edge cover,
the edge cover shared between the first light-emitting element and the third light-emitting element is a third shared edge cover,
the first shared edge cover includes a first portion and a second portion provided to the first edge cover, the first portion of the first edge cover being higher in height and the second portion of the first edge cover being lower in height,
the second shared edge cover includes a third portion and a fourth portion provided to the first edge cover, the third portion of the first edge cover being higher in height and the fourth portion of the first edge cover being lower in height,
the third shared edge cover includes a fifth portion and a sixth portion provided to the first edge cover, the fifth portion of the first edge cover being higher in height and the sixth portion of the first edge cover being lower in height,
the first portion and the fifth portion are provided near a first light-emitting layer that is the light-emitting layer included in the first light-emitting element,
the second portion and the third portion are provided near a second light-emitting layer that is the light-emitting layer included in the second light-emitting element, and
the fourth portion and the sixth portion are provided near a third light-emitting layer that is the light-emitting layer included in the third light-emitting element.

17. The display device according to claim 16,
wherein the first portion is as high in height as the fifth portion,
the second portion is as high in height as the third portion, and
the fourth portion is as high in height as the sixth portion.

18. The display device according to claim 16,
wherein the first shared edge cover, the second shared edge cover, and the third shared edge cover are equal in height.

19. A display device, comprising
a plurality of the light-emitting elements according to claim 4,
wherein the plurality of light-emitting elements include a first light-emitting element, a second light-emitting element, and a third light-emitting element,
the first light-emitting element emits light a center wavelength of which is closer to a long wavelength than a center wavelength of the second light-emitting element and a center wavelength of the third light-emitting element,
the second light-emitting element emits light the center wavelength of which is closer to a long wavelength than the center wavelength of the third light-emitting element,
the edge cover shared between the first light-emitting element and the second light-emitting element is a first shared edge cover,
the edge cover shared between the second light-emitting element and the third light-emitting element is a second shared edge cover,
the edge cover shared between the first light-emitting element and the third light-emitting element is a third shared edge cover,
the first edge cover of the first shared edge cover, the first edge cover of the second shared edge cover, and the first edge cover of the third shared edge cover are equal in height,
the first shared edge cover includes a seventh portion and an eighth portion provided to the second edge cover, the seventh portion of the second edge cover being higher in height and the eighth portion of the second edge cover being lower in height,
in the second shared edge cover, the second edge cover is constant in height,
the third shared edge cover includes a ninth portion and a tenth portion provided to the second edge cover, the ninth portion of the second edge cover being higher in height and the tenth portion of the second edge cover being lower in height,
the seventh portion and the ninth portion are provided near a first light-emitting layer that is the light-emitting layer included in the first light-emitting element,
the eighth portion and the second edge cover of the second shared edge cover are provided near a second light-emitting layer that is the light-emitting layer included in the second light-emitting element, and
the tenth portion and the second edge cover of the second shared edge cover are provided near a third light-emitting layer that is the light-emitting layer included in the third light-emitting element.

20. The display device according to claim 19,
wherein the seventh portion is as high in height as the ninth portion, and
the eighth portion, the tenth portion, and the second edge cover of the second shared edge cover are equal in height.

21. The display device according to claim 12,
wherein the first light-emitting element is a light-emitting element configured to emit a red light,
the second light-emitting element is a light-emitting element configured to emit a green light, and
the third light-emitting element is a light-emitting element configured to emit a blue light.
